(19) United States
(12) Patent Application Publication
(10) Pub. No.: US 2026/0019690 A1
(43) Pub. Date: Jan. 15, 2026

(54) CAMERA MODULE AND OPTICAL DEVICE

(71) Applicant: LG INNOTEK CO., LTD., Seoul (KR)

(72) Inventor: Chul Nae CHO, Seoul (KR)

(73) Assignee: LG INNOTEK CO., LTD., Seoul (KR)

(21) Appl. No.: 19/113,729

(22) PCT Filed: Sep. 20, 2023
(86) PCT No.: PCT/KR2023/014215

§ 371 Date: Mar. 20, 2025

(30) Foreign Application Priority Data
Sep. 22, 2022 (KR) 10-2022-0120341

(51) Int. Cl. H04N 23/54; H04N 23/55; H05K 1/11; H05K 1/14

(52) U.S. Cl. CPC H04N 23/54; H04N 23/55; H05K 1/111; H05K 1/147

(57) ABSTRACT

A camera module comprising: a lens holder in which lenses are disposed; a bracket disposed under the lens holder; a printed circuit board disposed at the lower portion of the bracket; and a stiffener disposed under the printed circuit board, wherein the lower surface of the bracket has a leg portion which protrudes further down than other areas so as to be coupled to the upper surface of the stiffener.

### TECHNICAL FIELD

The present embodiment relates to a camera module and an optical device.

### BACKGROUND ART

The content described below only provides background information for the present embodiment and does not describe prior art.

As various types of mobile terminals become more widespread and wireless Internet services become commercialized, consumer demands related to mobile terminals are also diversifying, and various types of additional devices are being installed in mobile terminals.

Among them, a representative one is a camera module that takes pictures or videos of a subject. Meanwhile, recent camera modules are equipped with an auto focus function that automatically adjusts the focus according to the distance to the subject. In addition, a shake correction function is applied to prevent the image from shaking due to the photographer's hand shake.

Meanwhile, various attempts are being made to reduce the size of the devices applied to the camera module for autofocus or image stabilization functions.

### DETAILED DESCRIPTION OF THE INVENTION

### Technical Subject

The present embodiment provides a camera module and optical device capable of reducing the size of a product.

### Technical Solution

A camera module of the present embodiment comprises: a lens holder in which a lens is disposed; a bracket being disposed under the lens holder; a printed circuit board being disposed at a lower portion of the bracket; and a stiffener being disposed at a lower portion of the printed circuit board, wherein a leg portion being protruded more downward than other regions and coupled to an upper surface of the stiffener is formed.

A metal pad is disposed on an upper surface of the printed circuit board, and a portion of a lower surface of the bracket can be soldered onto the metal pad.

A lower surface of the leg portion can be soldered to an upper surface of the stiffener.

The printed circuit board includes a cavity, and an image sensor facing the lens can be disposed in the cavity.

The bracket is provided with a bobbin being coupled with the lens, a first coil being disposed on the bobbin, and a first magnet being disposed on the outside of the first coil, and the first coil can be electrically connected to the printed circuit board through the metal pad.

The metal pad may be provided in multiple numbers and disposed to face one another.

A side surface of the leg portion may be spaced apart from a side surface of the printed circuit board.

The stiffener may include a first region facing the printed circuit board in an up and down direction, and a second region being disposed outside the first region and coupled with the leg portion.

The width of the second region can be 0.2 mm to 0.3 mm.

An optical device according to the present embodiment comprises: a main body; a camera module being disposed in the main body and photographing an image of a subject; and a display unit being disposed in the main body and outputting an image photographed by the camera module, wherein the camera module comprises: a lens holder in which a lens is disposed; a bracket being disposed at a lower portion of the lens holder; a printed circuit board being disposed at a lower portion of the bracket; and a stiffener being disposed under the printed circuit board, and wherein a lower surface of the bracket has a leg portion being protruded further down than other regions so as to be coupled to an upper surface of the stiffener.

### Advantageous Effects

Through the present embodiment, the size of the printed circuit board is reduced to the size of the formation region of the second region, so there is an advantage in that the manufacturing cost can be reduced.

In addition, due to the structure in which the bracket is soldered on the stiffener, there is an advantage in that it is easy to maintain the flatness of the bracket, and the bonding strength among the bracket, printed circuit board, and stiffener can be maintained firmly.

In addition, since the optical axis length of a camera module can be shortened by the thickness of the printed circuit board, there is an advantage in that the camera module can be further miniaturized.

### BRIEF DESCRIPTION OF DRAWINGS

FIG. 1 is a cross-sectional view of a camera module according to an embodiment of the present invention.

FIG. 2 is a plan view illustrating the upper surface of a printed circuit board according to an embodiment of the present invention.

FIG. 3 is a modified embodiment of a camera module according to an embodiment of the present invention.

FIG. 4 is a perspective view of an optical device according to an embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

The ‘optical axis direction’ used below is defined as the optical axis direction of the lens coupled to the camera module. Meanwhile, an ‘optical axis direction’ can correspond to an ‘up and down direction’, a ‘z-axis direction’, and the like.

The ‘auto focus function’ used below is defined as a function that automatically focuses on a subject by adjusting the distance from the image sensor by moving the lens module in an optical axis direction according to the distance to the subject so that a clear image of the subject can be obtained on an image sensor. Meanwhile, ‘auto focus’ can be used interchangeably with ‘auto focus (AF)’.

The ‘hand shake correction function’ used below is defined as a function that moves or tilts the lens module in a direction perpendicular to the optical axis direction to offset vibration (movement) caused to the image sensor by external force. Meanwhile, the ‘hand shake correction’ may be used interchangeably with ‘optical image stabilization (OIS)’.

Hereinafter, the present invention will be described in more detail with reference to the attached drawings.

FIG. 4 is a perspective view of an optical device according to an embodiment of the present invention.

The optical device may be any one among a mobile phone, a cellular phone, a smart phone, a portable smart device, a digital camera, a laptop computer, a digital broadcasting terminal, a personal digital assistant (PDA), a portable multimedia player (PMP), and a navigation device. However, the type of the optical device is not limited thereto, and any device for photographing images or pictures may be referred to as an optical device.

An optical device may include a main body 1, a display unit 2, and a camera module 10. However, in the optical device, any one or more among the main body 1, the display unit 2, and the camera module 10 may be omitted or changed.

The main body 1 may form an outer appearance of an optical device. As an example, the main body 1 may have a rectangular parallelepiped shape. As another example, the main body 1 may be rounded in at least in a portion. The main body 1 may accommodate the camera module 10. The display unit 2 may be disposed on one surface of the main body 1. As an example, the display unit 2 and the camera module 10 may be disposed on one surface of the main body 1, and the camera module 10 may be additionally disposed on the other surface (a surface located opposite to one surface) of the main body 1.

The display unit 2 may be disposed on the main body 1. The display unit 2 may be disposed on one surface of the main body 1. That is, the display unit 2 may be disposed on the same surface as the camera module 10. Alternatively, the display unit 2 may be disposed on the other surface of the main body 1. The display unit 2 may be disposed on the surface opposite to the surface on which the camera module 10 is disposed on the main body 1. The display unit 2 may output an image photographed by the camera module 10.

The camera module 10 may be disposed on the main body 1. The camera module 10 may be disposed on one surface of the main body 1. At least a portion of the camera module 10 may be accommodated inside the main body 1. A plurality of camera modules 10 may be provided. A plurality of camera modules 10 may be disposed on one surface of the main body 1 and the other surface of the main body 1. The camera module 10 may photograph an image of a subject.

Hereinafter, a configuration of a camera module according to the present embodiment will be described with reference to the drawings.

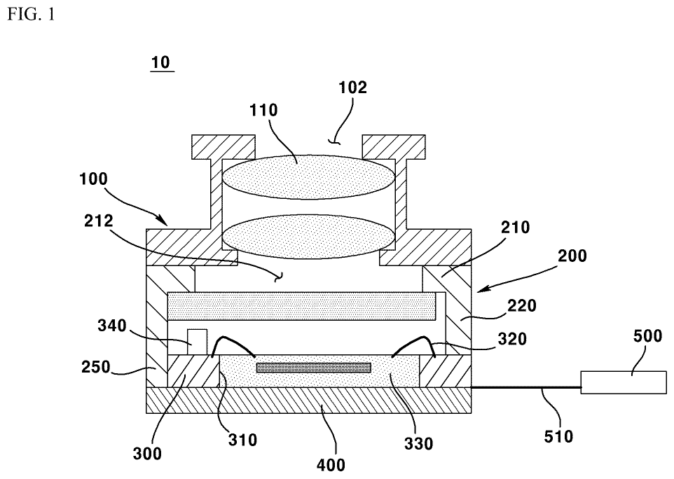

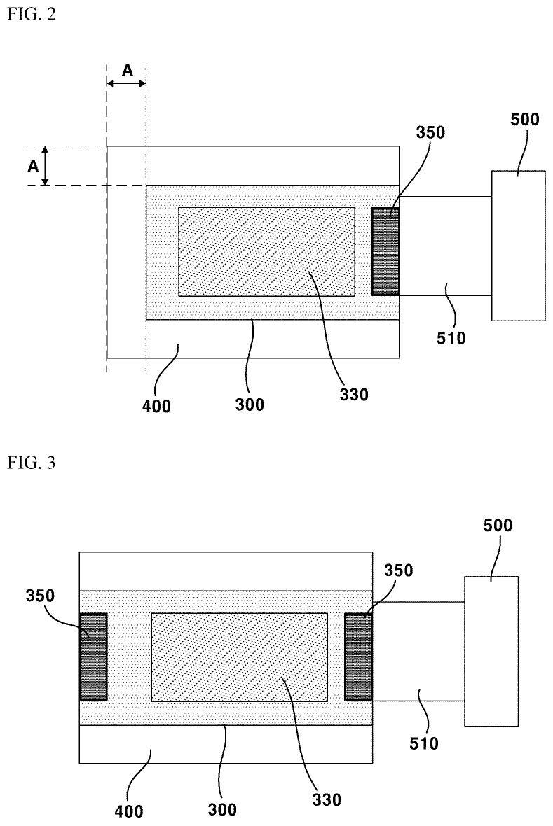

FIG. 1 is a cross-sectional view of a camera module according to an embodiment of the present invention; and FIG. 2 is a plan view illustrating the upper surface of a printed circuit board according to an embodiment of the present invention.

Referring to FIGS. 1 and 2, a camera module 10 according to an embodiment of the present invention may comprise a lens holder 100, a bracket 200, a printed circuit board 300, and a stiffener 400. However, in the camera module 10, any one or more among the lens holder 100, the bracket 200, the printed circuit board 300, and the stiffener 400 may be omitted or changed.

The lens holder 100 may accommodate at least one or more lens 110 inside. A space for accommodating the lens 110 may be formed in the lens holder 100. A hole 102 opening the space may be formed on the upper and lower surfaces of the lens holder 100, and the lens 110 may be exposed in an optical axis direction through the hole.

The lens holder 100 may be referred to as a lens barrel in that the lens 110 is accommodated inside.

The lens 110 may be disposed in a space inside the lens holder 100. The lens 110 may be screw-coupled inside the space. There may be at least one or more lens 110. For example, a plurality of lenses 110 may be provided and may be disposed to be spaced apart from one another in an optical axis direction inside the space. A spacer (not shown) may be disposed between pluralities of lenses.

The lens 110 may be aligned with an image sensor 330 to be described later. The lens 110 may be optically aligned with the image sensor 330. An optical axis of the lens 110 may correspond to an optical axis of the image sensor 330.

The bracket 200 may be disposed at a lower portion of the lens holder 100. An upper surface of the bracket 200 may be coupled to a lower surface of the lens holder 100. The bracket 200 may have a rectangular cross-sectional shape. A hole 212 may be formed in an upper surface of the bracket 200 being overlapped with the lens 110 in an optical axis direction. The lens 110 and the image sensor 330 may be optically aligned through the hole 212.

The bracket 200 may include an upper plate 210 and a side plate 220. The upper plate 210 may form an upper surface of the bracket 200. An upper surface of the upper plate 210 may be coupled to a lower surface of the lens holder 100. The hole 212 may be formed at the center of the upper plate 210.

The side plate 220 may form a side surface of the bracket 200. The side plate 220 may be formed to be bent from an edge region of the upper plate 210 and extended downward. The side plate 220 may be disposed perpendicular to the upper plate 210. Two or more step regions having different heights may be formed at the lower end of the side plate 220.

An infrared ray filter 230 may be disposed between the lens 110 and the image sensor 330. The infrared filter 230 may be disposed in a space inside the bracket 200. The infrared filter 230 may be coupled to a lower surface of the upper plate 210.

An actuator (not shown) for moving the lens 110 to perform an optical function may be provided in the bracket 200. Through the actuator, the camera module 10 may perform an auto-focusing (AF) function, hand shake correction and an optical image stabilizer (OIS) function, and the like.

The actuator may include a housing, a bobbin being disposed inside the housing to which the lens 110 is coupled, a coil being disposed on an outer circumferential surface of the bobbin, and a first magnet being disposed in the housing and facing the coil. In addition, the actuator may include an elastic member being coupled to the housing and the bobbin. Accordingly, by the electromagnetic interaction between the coil and the magnet, the bobbin may rotate together with the lens 110.

Meanwhile, the coil may include a first coil for an auto-focusing function and a second coil for a hand shake correction function. In this case, a second magnet facing the second coil may be additionally provided on an outer side of the second coil. Accordingly, the bobbin may move in an optical axis direction by the electromagnetic interaction between the first coil and the first magnet, and the bobbin may move in a direction perpendicular to the optical axis direction by the electromagnetic interaction between the second coil and the second magnet.

The above first coil and the above second coil can be electrically connected to the printed circuit board 300.

The printed circuit board 300 may be disposed at a lower portion of the bracket 200. The printed circuit board 300 is formed in a plate shape, and at least one electronic component for driving the camera module 10 may be disposed on an upper surface thereof. For example, the electronic component may include a capacitor 340.

The printed circuit board 300 may have a rectangular cross-sectional shape. The printed circuit board 300 may include a first side, a second side being disposed to face the first side, a third side being disposed adjacent to the first side and the second side, and a fourth side being disposed to face the third side and adjacent to the first side and the second side. The lengths of the first side and the second side may be formed to be smaller than the lengths of the third side and the fourth side.

The printed circuit board 300 may include a cavity 310. The cavity 310 may have a hole shape penetrating from an upper surface to a lower surface of the printed circuit board 300. The cavity 310 may have a groove shape being formed to be recessed further downward from the upper surface of the printed circuit board 300 than other regions. The cavity 310 may be disposed at a center of the printed circuit board 300. The cross-sectional shape of the cavity 310 may be formed to correspond to the cross-sectional shape of the image sensor 330.

An image sensor 330 may be disposed in the cavity 310. The image sensor 330 may be disposed to face the lens 110 in an optical axis direction. The upper surface of the image sensor 330 may be disposed to form the same plane as the upper surface of the printed circuit board 300.

The image sensor 330 may be electrically coupled to the printed circuit board 300 through a wire 320. One end of the wire 320 is coupled on to the image sensor 330 and the other end may be coupled on to the printed circuit board 300. A plurality of wires 320 may be provided and disposed to be spaced apart from one another

A metal pad 350 may be disposed on an upper surface of the printed circuit board 300. The metal pad 350 may be a region in which the circuit pattern in the printed circuit board 300 is exposed upward. The metal pad 350 may be formed of a metal material. The metal pad 350 may be disposed adjacent to the second side. A lower end of the bracket 200 may be coupled to the metal pad 350. A portion of a lower end of the bracket 200 may be coupled to the metal pad 350 by welding.

By the coupling of the bracket 200 and the metal pad 350, the first coil inside the bracket 200 can be electrically connected to the printed circuit board 300.

The camera module 10 may include a sub-substrate 500. The sub-substrate 500 may be electrically connected to the printed circuit board 300 through an FPCB 510. The sub-substrate 500 may be disposed outside the printed circuit board 300. An external connector electrically connected to an external power source or other devices may be disposed on the sub-substrate 500. One end of the FPCB 510 for connection with the sub-substrate 500 may be coupled to the second side of the printed circuit board 300 on which the metal pad 350 is disposed. One end of the FPCB 510 may be soldered to the metal pad 350 together with the bracket 200.

The stiffener 400 may be disposed on a lower surface of the printed circuit board 300. The stiffener 400 may be formed in a plate shape. The stiffener 400 may be formed of a metal material. An upper surface of the stiffener 400 may support a lower surface of the printed circuit board 300 and a lower surface of the image sensor 330. The rigidity of the printed circuit board 300 to which the image sensor 330 is coupled may be enhanced through the stiffener 400.

The stiffener 400 may have a rectangular cross-sectional shape. The cross-sectional area of the stiffener 400 may be larger than the cross-sectional area of the printed circuit board 300.

The above stiffener 400 may include a first region disposed to be overlapped with the printed circuit board 300 in the up and down directions, and a second region disposed on the outside of the first region. The second region may be disposed so as not to be overlapped with the printed circuit board 330. As illustrated in FIG. 2, the second region may have a cross-section having an approximately “⊂” shape. The second region may be disposed on the outside of the first side, the third side, and the fourth side of the printed circuit board 300.

The width A of the second region may be 0.2 mm to 0.3 mm.

The bracket 200 may include a leg region 250. The leg region 250 may have a shape being protruded downward from the lower surface of the bracket 200 than other regions. That is, the leg region 250 may have a shape being extended downward from the side plate 220. The leg region 250 may be disposed to be overlapped with the printed circuit board 300 in a direction perpendicular to the optical axis direction. The leg region 250 may be disposed to be overlapped with the second region of the stiffener 400 in an optical axis direction. The lower surface of the leg region 250 may be coupled to the upper surface of the stiffener 400. The lower surface of the leg region 250 may be coupled to the upper surface of the stiffener 400. The lower surface of the leg region 250 may be soldered to the upper surface of the stiffener 400. The cross-sectional shape of the leg region 250 may be formed to correspond to the cross-sectional shape of the second region.

The leg region 250 may be disposed outside the first side, the third side, and the fourth side of the printed circuit board 300. Specifically, when the cross section of the bracket 200 is formed in a rectangular shape, the bracket 200 may include a fifth side where the leg region 250 is formed, a sixth side and a seventh side, which are adjacent to the fifth side and are similarly formed with the leg portion, and an eighth side being disposed to face the fifth side and soldered on the metal pad 350. The lower surfaces of the fifth side, the sixth side, and the seventh side, which are formed at a lower end of the leg region 250, may be disposed at a lower side than the lower surface of the eighth side.

The side surface of the leg portion 250 may be spaced apart from the side surface of the printed circuit board 300. Unlike this, the side surface of the leg portion 250 may be in contact with the side surface of the printed circuit board 300.

According to the above structure, the size of the printed circuit board is reduced by the size of the second region forming region, so there is an advantage in that the manufacturing cost can be lowered.

In addition, there is an advantage in that since the bracket is soldered on the stiffener, it is easy to maintain the flatness of the bracket, and the bonding strength between the bracket, printed circuit board, and stiffener can be maintained firmly.

In addition, since the optical axis direction length of the camera module can be shortened by the thickness of the printed circuit board, there is an advantage in that the camera module can be more miniaturized.

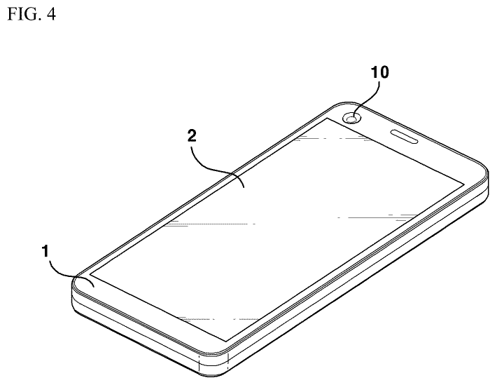

FIG. 3 is a modified embodiment of a camera module according to an embodiment of the present invention.

Referring to FIG. 3, in the present modified embodiment, since a plurality of metal pads 350 are provided on the printed circuit board 300, there is a difference in the shape of the printed circuit board 300 and the arrangement structure with the stiffener 400.

Specifically, in the present modified embodiment, a plurality of metal pads 350 is provided to be adjacent to the first side and the second side of the printed circuit board 300, and the second region of the stiffener 400 may be disposed outside the third side and the fourth side of the printed circuit board 300.

Accordingly, the leg portion 250 is formed only on the sixth and seventh sides of the bracket 200, and lower surfaces of the fifth and eighth sides may be soldered onto the plurality of metal pads 350 respectively.

In the present modified embodiment, by a plurality of bonding regions between the bracket 200 and the printed circuit board 300, any one among the plurality of metal pads 350 can be electrically connected to a first coil for the AF function, and the other one can be electrically connected to a second coil for the OIS function.

In the above description, it is described that all the components constituting the embodiments of the present invention are combined or operated in one, but the present invention is not necessarily limited to these embodiments. In other words, within the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas within the equivalent scope should be interpreted as being included in the scope of the present invention.

1.-10. (canceled)

11. A camera module comprising:
a lens holder in which a lens is disposed;
a bracket disposed under the lens holder;
a printed circuit board disposed at a lower portion of the bracket; and
a stiffener disposed at a lower portion of the printed circuit board,
wherein a leg portion protruded more downward than other regions and coupled to an upper surface of the stiffener is formed.

12. The camera module according to claim 11, wherein a metal pad is disposed on an upper surface of the printed circuit board, and
wherein a portion of a lower surface of the bracket can be soldered onto the metal pad.

13. The camera module according to claim 11, wherein a lower surface of the leg portion is soldered to an upper surface of the stiffener.

14. The camera module according to claim 11, wherein the printed circuit board includes a cavity, and
wherein an image sensor facing the lens is disposed in the cavity.

15. The camera module according to claim 12, wherein the bracket is provided with a bobbin being coupled with the lens, a first coil disposed on the bobbin, and
wherein a first magnet disposed on the outside of the first coil, and the first coil can be electrically connected to the printed circuit board through the metal pad.

16. The camera module according to claim 12, wherein the metal pad is provided in multiple numbers and disposed to face one another.

17. The camera module according to claim 11, wherein a side surface of the leg portion is spaced apart from a side surface of the printed circuit board.

18. The camera module according to claim 11, wherein the stiffener includes a first region facing the printed circuit board in an up and down direction, and a second region disposed outside the first region and coupled with the leg portion.

19. The camera module according to claim 18, wherein the width of the second region is 0.2 mm to 0.3 mm.

20. The camera module according to claim 12, wherein the printed circuit board includes a first side, a second side arranged opposite the first side, a third side adjacent to the first side and the second side, and a fourth side arranged opposite the third side,
wherein the leg portion is arranged on an outer side of the first side, the third side, and the fourth side, and
wherein the metal pad is arranged adjacent to the second side.

21. The camera module according to claim 12, wherein the printed circuit board includes a first side, a second side arranged opposite the first side, a third side adjacent to the first side and the second side, and a fourth side arranged opposite the third side,
wherein the leg portion is arranged on an outer side of the third side and the fourth side, and
wherein the metal pad is provided in multiple numbers and arranged adjacent to the first side and the second side.

22. The camera module according to claim 11, wherein a side of the leg portion is in contact with a side of the printed circuit board.

23. The camera module according to claim 21, comprising a sub-board electrically connected to the printed circuit board through an FPCB.

24. The camera module according to claim 23, wherein the FPCB is coupled to the second side.

25. The camera module according to claim 11, wherein a cross-sectional area of the stiffener is larger than across-sectional area of the printed circuit board.

26. An optical device comprising:
a main body;
a camera module disposed in the main body and configured to photograph an image of a subject; and
a display unit disposed in the main body and configured to output an image photographed by the camera module,
wherein the camera module comprises:
a lens holder in which a lens is disposed;
a bracket disposed at a lower portion of the lens holder;
a printed circuit board disposed at a lower portion of the bracket; and
a stiffener disposed under the printed circuit board, and
wherein a lower surface of the bracket has a leg portion protruded further down than other regions so as to be coupled to an upper surface of the stiffener.

27. The optical device according to claim 26, wherein a metal pad is disposed on an upper surface of the printed circuit board, and
wherein a portion of a lower surface of the bracket can be soldered onto the metal pad.

28. The optical device according to claim 26, wherein a lower surface of the leg portion is soldered to an upper surface of the stiffener.

29. The optical device according to claim 26, wherein the printed circuit board includes a cavity, and
wherein an image sensor facing the lens is disposed in the cavity.

30. The optical device according to claim 26, wherein the bracket is provided with a bobbin being coupled with the lens, a first coil disposed on the bobbin, and
wherein a first magnet disposed on the outside of the first coil, and the first coil can be electrically connected to the printed circuit board through the metal pad.
